(19) United States
(12) Patent Application Publication
(10) Pub. No.: US 2015/0021731 A1
(43) Pub. Date: Jan. 22, 2015

(54) SOLID-STATE IMAGING DEVICE AND MANUFACTURING METHOD THEREOF

(71) Applicant: Panasonic Intellectual Property Management Co., Ltd., Osaka (JP)

(72) Inventors: KEISUKE YAZAWA, Osaka (JP); YUTAKA HIROSE, Kyoto (JP); YOSHIHISA KATO, Shiga (JP)

(21) Appl. No.: 14/511,737

(22) Filed: Oct. 10, 2014

Related U.S. Application Data
(63) Continuation of application No. PCT/JP2013/001043, filed on Feb. 25, 2013.

(30) Foreign Application Priority Data
Apr. 19, 2012 (JP) 2012-095316

(51) Int. Cl. H01L 27/146; H01L 31/0224; H01L 31/109; H01L 31/108

(52) U.S. Cl. CPC H01L 27/14649; H01L 31/108; H01L 31/022408; H01L 31/109; H01L 27/14687
USPC 257/448; 438/73

(57) ABSTRACT

The solid-state imaging device according to the present invention includes a semiconductor substrate including an imaging region and a peripheral circuit region, a wiring layer formed on the semiconductor substrate, a plurality of pixel electrodes arranged in a matrix on the wiring layer above the imaging region, a photoelectric conversion film formed on the wiring layer and the plurality of pixel electrodes above the imaging region, and an upper electrode formed on the photoelectric conversion film. The photoelectric conversion film has a laminated structure in which a plurality of well layers and a plurality of barrier layers are alternately laminated, the well layers made of a first semiconductor having a fundamental absorption edge in a wavelength region longer than a near-infrared light wavelength, and the barrier layers made of an insulator or a second semiconductor having a band gap wider than that of the first semiconductor.

### BACKGROUND

1. Technical Field

The present invention relates to a solid-state imaging device and a manufacturing method thereof, and more particularly to a photoelectric conversion unit in a laminated solid-state imaging device.

2. Background Art

A solid-state imaging device has been developed to have many pixels, and with this development, another development for reducing a pixel size is actively made. When the pixel size is reduced, a number of photons incident on one pixel is reduced to deteriorate sensitivity. However, a monitoring camera needs a solid-state imaging device that can photograph even at a dark place. Under such a background, improvement in sensitivity of a solid-state imaging device has been a subject for study.

Japanese Patent No. 2959460 describes a photoelectric conversion film laminated solid-state imaging device in which a photoelectric conversion film is arranged above a semiconductor substrate, as a high-sensitive solid-state imaging device.

INTERNATIONAL ELECTRON DEVICES MEETING 10 344-347 describes a solid-state imaging device employing Ge for a photodiode for enhancing sensitivity.

### SUMMARY

However, even if Ge is used for a photoelectric conversion film of a photoelectric conversion film laminated solid-state imaging device, a semiconductor having a fundamental absorption edge in a wavelength region longer than a near-infrared light wavelength has a narrow band gap. Therefore, intrinsic carrier concentration ni increases, and a barrier height Φ decreases, whereby dark current increases. When Ge is used for a photoelectric conversion film in a photoelectric conversion film laminated solid-state imaging device, dark current increases. Therefore, this device is difficult to be used at room temperature.

The present invention aims to prevent dark current in a solid-state imaging device that uses a semiconductor, which has a fundamental absorption edge in a wavelength region longer than a near-infrared light wavelength having a high absorption coefficient, for a photoelectric conversion film.

A solid-state imaging device according to the present invention includes a semiconductor substrate including an imaging region and a peripheral circuit region, and a wiring layer formed on the semiconductor substrate. The solid-state imaging device according to the present invention also includes a plurality of pixel electrodes arranged in a matrix on the wiring layer above the imaging region, a photoelectric conversion film formed on the wiring layer and the plurality of pixel electrodes above the imaging region, and an upper electrode formed on the photoelectric conversion film The photoelectric conversion film has a laminated structure in which a plurality of well layers and a plurality of barrier layers are alternately laminated, each of the well layers being made of a first semiconductor having a fundamental absorption edge in a wavelength region longer than a near-infrared light wavelength, and each of the barrier layers being made of an insulator or a second semiconductor having a band gap wider than that of the first semiconductor.

A manufacturing method of a solid-state imaging device according to the present invention includes forming a wiring layer on a semiconductor substrate including an imaging region and a peripheral circuit region; and forming a plurality of pixel electrodes arranged in a matrix on the wiring layer above the imaging region. The manufacturing method of a solid-state imaging device according to the present invention also includes forming a photoelectric conversion film on the wiring layer and the plurality of pixel electrodes above the imaging region; and forming an upper electrode on the photoelectric conversion film In the process of forming the photoelectric conversion film, a plurality of well layers and a plurality of barrier layers are alternately laminated, each of the well layers being made of a first semiconductor having a fundamental absorption edge in a wavelength region longer than a near-infrared light wavelength, and each of the barrier layers being made of an insulator or a second semiconductor having a band gap wider than that of the first semiconductor.

According to the solid-state imaging device and the manufacturing method thereof, a solid-state imaging device that has high sensitivity and that reduces dark current can be realized.

### BRIEF DESCRIPTION OF DRAWINGS

FIG. 1 is a block diagram illustrating a solid-state imaging device according to a first exemplary embodiment.

FIG. 2 is a sectional view illustrating an imaging region of the solid-state imaging device according to the first exemplary embodiment.

FIG. 3 is an enlarged view illustrating a photoelectric conversion unit of the solid-state imaging device according to the first exemplary embodiment.

FIG. 4 is an energy diagram of an upper electrode, the photoelectric conversion unit, and a pixel electrode of the solid-state imaging device according to the first exemplary embodiment.

FIG. 5 is an energy diagram of an upper electrode, a photoelectric conversion unit, and a pixel electrode of a solid-state imaging device according to a first modification of the first exemplary embodiment.

FIG. 6 is an energy diagram of an upper electrode, a photoelectric conversion unit, and a pixel electrode of a solid-state imaging device according to a second modification of the first exemplary embodiment.

FIG. 7 is an energy diagram of an upper electrode, a photoelectric conversion unit, and a pixel electrode of a solid-state imaging device according to a third modification of the first exemplary embodiment.

FIG. 8 is an energy diagram of an upper electrode, a photoelectric conversion unit, and a pixel electrode of a solid-state imaging device according to a fourth modification of the first exemplary embodiment.

FIG. 9 is an energy diagram of an upper electrode, a photoelectric conversion unit, and a pixel electrode of a solid-state imaging device according to a fifth modification of the first exemplary embodiment.

FIG. 10 is a graph illustrating dependency of dark current on a thickness of Ge in the photoelectric conversion unit of the solid-state imaging device according to the first exemplary embodiment.

FIG. 11 is an enlarged view illustrating a photoelectric conversion unit of a solid-state imaging device according to a second exemplary embodiment.

FIG. 12 is an energy diagram of an upper electrode, the photoelectric conversion unit, and a pixel electrode of the solid-state imaging device according to the second exemplary embodiment.

FIG. 13 is an energy diagram of the upper electrode, the photoelectric conversion unit, and the pixel electrode of the solid-state imaging device according to the second exemplary embodiment.

FIG. 14 is a sectional view illustrating a manufacturing method of a solid-state imaging device according to a third exemplary embodiment.

FIG. 15 is a sectional view illustrating the manufacturing method of the solid-state imaging device according to the third exemplary embodiment.

FIG. 16 is a sectional view illustrating the manufacturing method of the solid-state imaging device according to the third exemplary embodiment.

### DESCRIPTION OF EMBODIMENTS

### First Exemplary Embodiment

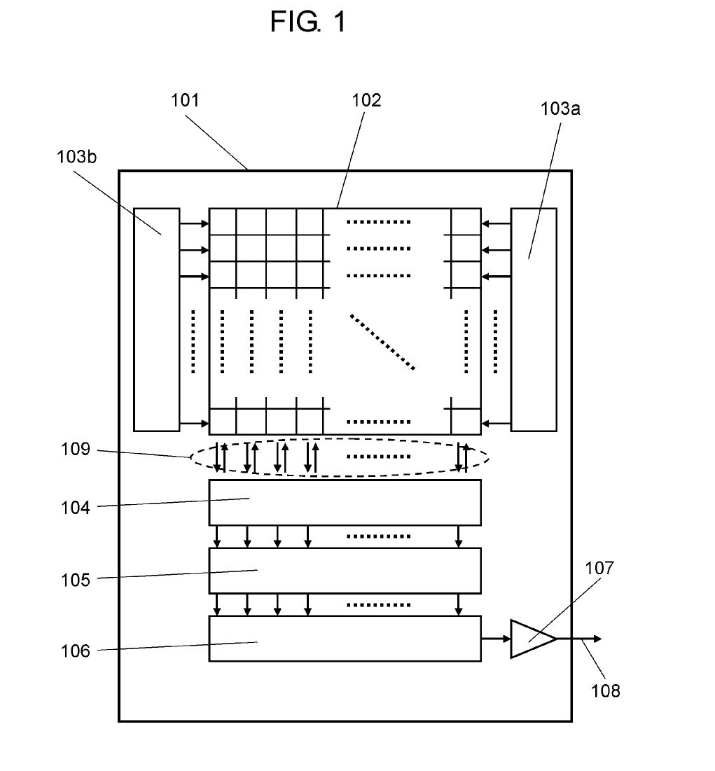

The first exemplary embodiment of the present invention will be described with reference to FIGS. 1 to 10.

FIG. 1 is a block diagram illustrating a configuration of a solid-state imaging device according to the present exemplary embodiment. Solid-state imaging device 101 according to the present exemplary embodiment includes imaging region 102 where a plurality of pixels are arrayed (arranged) in a matrix, and vertical drive circuits 103a and 103b that send a row signal to imaging region 102.

Solid-state imaging device 101 also includes horizontal feedback amplifier circuit 104 in which a plurality of circuits having an amplifying function and a feedback function, corresponding to each row of imaging region 102, are arranged. Solid-state imaging device 101 also includes noise canceller circuit 105 that reduces noise in the signal from horizontal feedback amplifying circuit 104, and horizontal drive circuit 106 that sends a signal from noise canceller circuit 105 in a horizontal direction. Solid-state imaging device 101 outputs a signal to an outside of solid-state imaging device 101 from output 108 via output stage amplifier 107 that amplifies a signal from horizontal drive circuit 106.

Horizontal feedback amplifier circuit 104 receives the output signal from imaging region 102, and feeds back this signal. Therefore, the flowing direction of the signal becomes bidirectional to imaging region 102 as indicated by reference numeral 109.

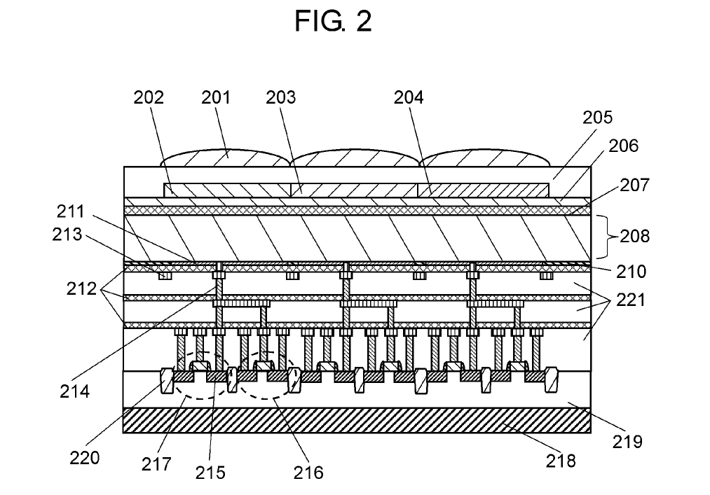

FIG. 2 is a sectional view illustrating imaging region 102 corresponding to three pixels. Actual solid-state imaging device 101 includes ten million pixels arrayed in a matrix. Microlens 201 is formed on the uppermost surface in order to effectively focus incident light.

In order to capture a color image, red color filter 202, green color filter 203, and blue color filter 204 are formed just below each microlens in protection film 205. These optical elements are formed on flattened film 206 made of a silicon nitride film for forming microlens 201 and color filter group, which cause neither uneven light condensation nor color unevenness, for ten million pixels. Below flattened film 206, upper electrode 207 that is made of ITO (Indium Tin Oxide) and transmits visible light is formed on the entire surface of imaging region 102.

Photoelectric conversion film 208 formed by alternately laminating Ge and SiO₂ is formed below upper electrode 207. This photoelectric conversion film 208 is referred to as a Ge/SiO₂ superlattice photoelectric conversion film, in particular. The Ge/SiO₂ photoelectric conversion film absorbs 99% of red light with a wavelength of 650 nm. Pixel electrode 211 made of Al is formed below photoelectric conversion film 208. Pixel electrode 211 is formed on flattened diffusion prevention film 212 having a thickness of 100 nm. Each of pixel electrodes 211 is separated with an interval of 0.2 μm. Insulating film 210 is formed between pixel electrodes 211.

A wiring layer including wire 213, via 214, interlayer insulating film 221, and diffusion prevention film 212 is formed below pixel electrode 211. Wire 213 and via 214 are made of copper, and diffusion prevention film 212 prevents diffusion of copper into interlayer insulating film 221.

Each pixel electrode 211 is connected to floating diffusion portion 215 formed in P-type well 219 of silicon substrate 218 and connected to an input gate of amplifying transistor 216 through wire 213 and via 214 of the wiring layer.

Floating diffusion portion 215 shares its region with a source portion of reset transistor 217, and they are electrically connected. Sources and drains of amplifying transistor 216, reset transistor 217, and selection transistor (not illustrated), and floating diffusion portion 215 are formed in P-type well 219. Each transistor is electrically isolated by STI region 220 (Shallow Trench Isolation) made of a silicon oxide film.

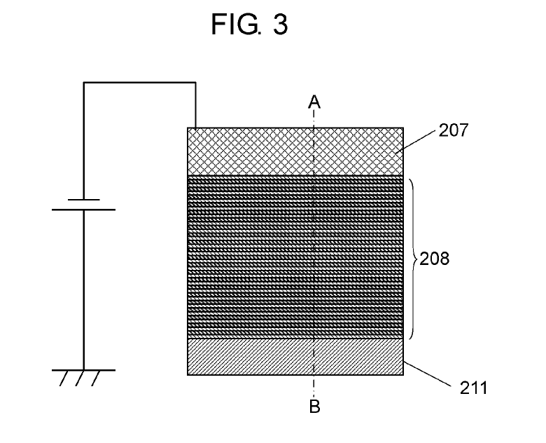

FIG. 3 is an enlarged view of upper electrode 207, photoelectric conversion film 208, and pixel electrode 211.

As illustrated in FIG. 3, photoelectric conversion film 208 is a superlattice photoelectric conversion film, and includes 76 silicon oxide film layers, each having a thickness of 2 nm, and 75 Ge layers, each having a thickness of 1.2 nm. Each of the silicon oxide film layers and each of the Ge layers are alternately laminated. The present exemplary embodiment describes the thickness and the number of layers as one example. However, the present invention is not limited thereto. The superlattice photoelectric conversion film is formed by alternately laminating the thin silicon oxide film layer and the thin Ge layer, which have a different band gap. With this structure, the superlattice photoelectric conversion film is formed as a pseudo photoelectric conversion film having a band gap between the band gap of the silicon oxide film layer and the band gap of the Ge layer. This will be described below in more detail.

As illustrated in FIG. 3, negative voltage is applied to upper electrode 207, whereby electrons generated in photoelectric conversion film 208 become carriers, move to pixel electrode 211, and become a signal.

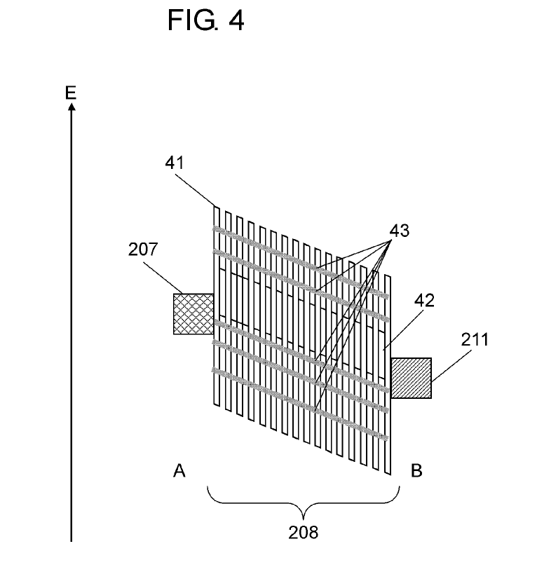

FIG. 4 is an energy diagram illustrating an energy band structure in a cross-sectional direction (A-B) from upper electrode 207 to pixel electrode 211 in FIG. 3. In FIG. 4, a vertical axis indicates energy, and a horizontal axis indicates a distance between upper electrode 207 and pixel electrode 211.

As illustrated in FIG. 4, silicon oxide film layer 41 is on both terminal ends of the superlattice photoelectric conversion film formed by alternately laminating silicon oxide film layer 41 and Ge layer 42. ITO of upper electrode 207 and Al of pixel electrode 211 are connected via silicon oxide film layer 41.

Specifically, each of a layer in contact with pixel electrode 211 and a layer in contact with upper electrode 207 in photoelectric conversion film 208 is one of a plurality of barrier layers.

A rectangular period potential made of an upper end of a valence band and a lower end of a conductive band of silicon oxide film layer 41 and Ge layer 42 is confirmed. When the thickness of silicon oxide film layer 41 is thin (about 5 nm or less) to such an extent that mutual interaction is caused between adjacent wells, resonance between the adjacent wells occurs, whereby miniband 43 is formed on the valence band and the conductive band. As for the band gap including the upper end of the valence band and the lower end of the conductive band, the band gap of the superlattice photoelectric conversion film is increased to 1.7 eV by the insertion of the thin silicon oxide film, although the band gap of germanium is 0.66 eV.

Charges (in the present exemplary embodiment, electrons) generated by the photoelectric conversion are accelerated to pixel electrode 211 via superlattice miniband 43 by an electric field applied between upper electrode 207 and pixel electrode 211, and transferred to floating diffusion portion 215 from pixel electrode 211. When Ge layer 42 is made of a non-doped (intrinsic) semiconductor, the energy form illustrated in FIG. 4 is obtained.

### (First Modification of First Exemplary Embodiment)

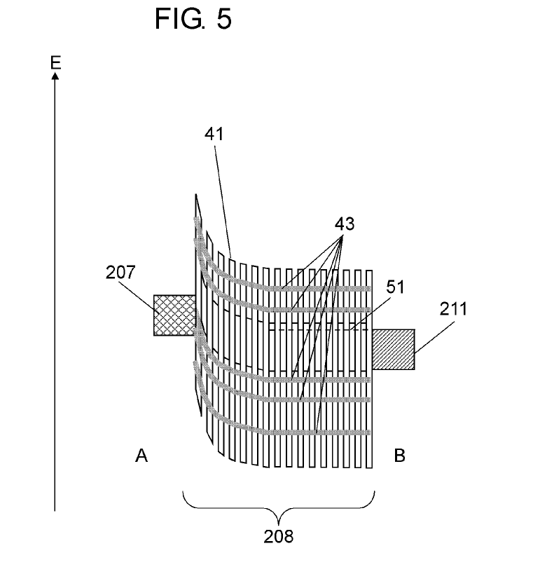

FIG. 5 is an energy diagram for describing a first modification of the present first exemplary embodiment. Specifically, FIG. 5 is an energy diagram illustrating an energy band structure in a cross-sectional direction (A-B) from upper electrode 207 to pixel electrode 211, wherein Ge layer 51 is formed as N-type semiconductor. In FIG. 5, a vertical axis indicates energy, and a horizontal axis indicates a distance between upper electrode 207 and pixel electrode 211.

As illustrated in FIG. 5, N-type Ge layer 51 is used for the well layer to form a Schottky contact with upper electrode 207. With this structure, Ge near the bonding portion is depleted to form a Schottky diode, whereby reverse saturation current can be made to serve as dark current.

Specifically, out of the plurality of well layers, at least the well layer close to upper electrode 207 has a first conductive type, and photoelectric conversion film 208 forms a Schottky contact with upper electrode 207 through the barrier layer in contact with upper electrode 207. The whole well layers may have the first conductive type.

N-type Ge layer 51 can be formed by doping impurity such as phosphor or arsenic into Ge.

### (Second Modification of First Exemplary Embodiment)

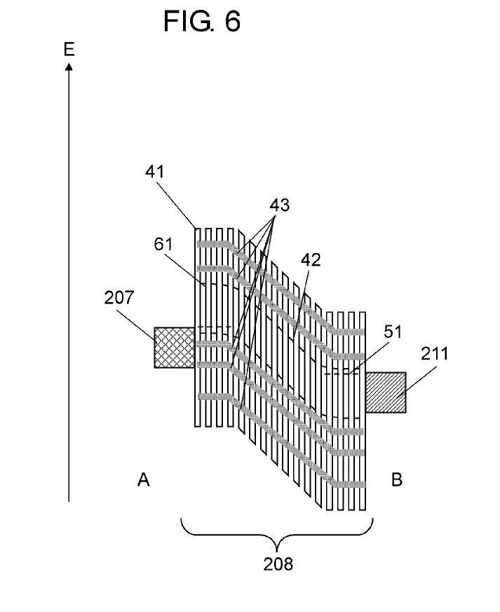

FIG. 6 is an energy diagram for describing a second modification of the present first exemplary embodiment. Specifically, FIG. 6 is an energy diagram illustrating an energy band structure in a cross-sectional direction (A-B) from upper electrode 207 to pixel electrode 211, wherein Ge layer 51 is formed as an N-type semiconductor, and Ge layer 61 is formed as a P-type semiconductor.

As illustrated in the band structure in FIG. 6, P-type Ge layer 61 is used for the well layer close to upper electrode 207, and N-type Ge layer 51 is used for the well layer close to pixel electrode 211, whereby Ge around non-doped Ge layer 42 is depleted. Thus, a P-I-N diode is formed, whereby reverse saturation current can be made to serve as dark current.

Specifically, out of the plurality of well layers, the well layer close to pixel electrode 211 has a first conductive type, and photoelectric conversion film 208 forms an ohmic contact with pixel electrode 211 through the barrier layer in contact with pixel electrode 211. Out of the plurality of well layers, the well layer close to upper electrode 207 has a second conductive type opposite to the first conductive type, and photoelectric conversion film 208 forms an ohmic contact with upper electrode 207 through the barrier layer in contact with upper electrode 207.

P-type Ge layer 61 can be formed by doping impurities such as boron into Ge, and N-type Ge layer 51 can be formed by doping impurities such as phosphor or arsenic into Ge.

### (Third Modification of First Exemplary Embodiment)

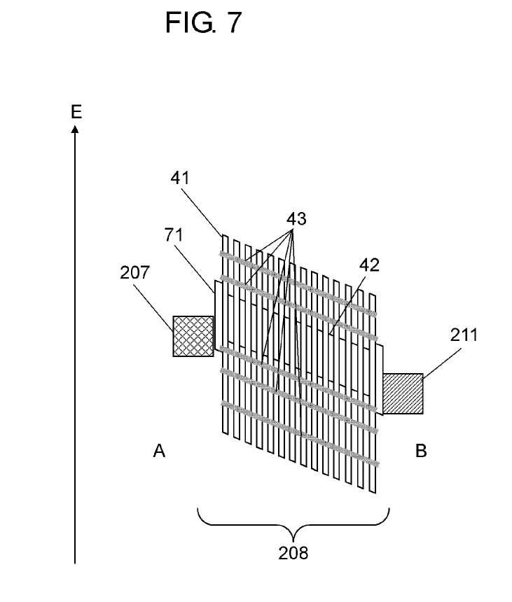

FIG. 7 is an energy diagram for describing a third modification of the present first exemplary embodiment. FIG. 7 is the energy diagram illustrating an energy band structure in a cross-sectional direction (A-B) from upper electrode 207 to pixel electrode 211, wherein Ge layer 71 is located at terminal ends of the superlattice photoelectric conversion film.

The similar effect is obtained by bringing upper electrode 207 and pixel electrode 211 into direct contact with Ge layer 42 that is the well layer. A semiconductor material that is in contact with the electrode can be changed. If a Si window layer having a larger band gap than Ge layer 71 is used, in particular, a window effect is exhibited, whereby a loss of signal charge caused by a surface recombination can be prevented.

Specifically, each of a layer in contact with pixel electrode 211 and a layer in contact with upper electrode 207 in photoelectric conversion film 208 is made of third semiconductor having a narrower band gap than the barrier layer.

In addition, an apparent band structure of the superlattice layer and the band structure of Si form an interface having no band discontinuity, whereby optically excited signal charges can easily be extracted.

### (Fourth Modification of First Exemplary Embodiment)

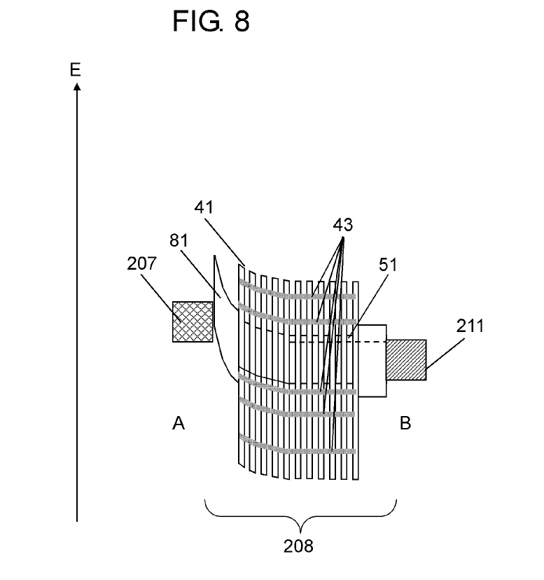

FIG. 8 is an energy diagram for describing a fourth modification of the present first exemplary embodiment. FIG. 8 is an energy diagram illustrating an energy band structure in a cross-sectional direction (A-B) from upper electrode 207 to pixel electrode 211. Ge layer 51 is the N-type semiconductor as in the first modification, and N-type Si window layer 81 is located at terminal ends of the superlattice photoelectric conversion film as in the third modification.

In FIG. 8, upper electrode 207 and N-type Si window layer 81 at the terminal end form a Schottky junction to form a Schottky diode, in order to reduce dark current.

Specifically, the third semiconductor in contact with upper electrode 207 has a first conductive type, and forms the Schottky contact with upper electrode 207.

Thus, reverse saturation current can be made to serve as dark current.

### (Fifth Modification of First Exemplary Embodiment)

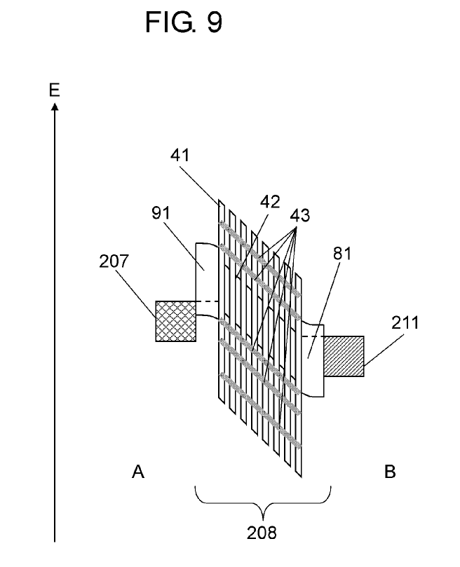

FIG. 9 is an energy diagram for describing a fifth modification of the present first exemplary embodiment. In FIG. 9, Ge layer 42 is non-doped, and Si window layers 81 and 91 that are two semiconductors at terminal ends of the superlattice photoelectric conversion film are formed to have a different conductive type by doping impurities, whereby P-I-N diode is formed.

Specifically, the third semiconductor in contact with pixel electrode 211 has a first conductive type, and forms an ohmic contact with pixel electrode 211. The third semiconductor in contact with upper electrode 207 has a second conductive type opposite to the first conductive type, and forms an ohmic contact with upper electrode 207.

Thus, reverse saturation current can be made to serve as dark current.

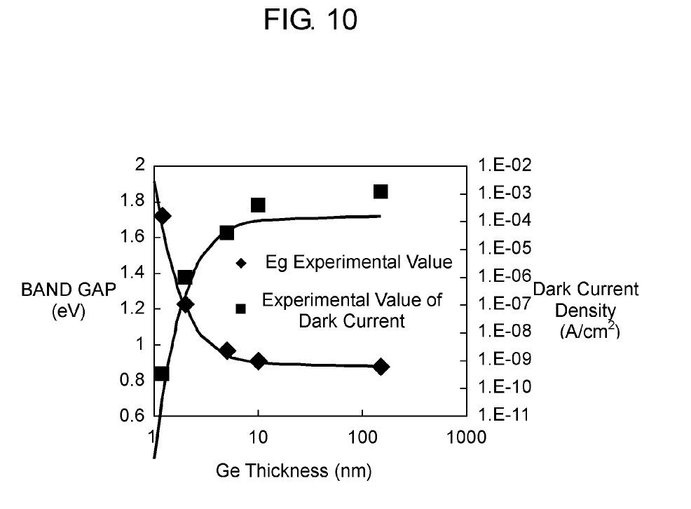

FIG. 10 is a graph illustrating a dependency of dark current on a thickness of a Ge layer in the structure of the present first exemplary embodiment. It can be seen from the graph that, in the superlattice structure with Ge thickness a of 2 nm, dark current can be reduced to 10⁻⁶ A/cm² even if a diode is not formed. When a diode is formed as described above, the effect of further reducing dark current can be obtained, and this structure can be used as a photoelectric conversion film of a solid-state imaging device at room temperature. In a silicon photodiode, dark current is 10⁻¹⁰ A/cm². It can be seen that the effect of reducing dark current more than the silicon photodiode can be obtained, when a superlattice structure with Ge thickness a of 1.2 nm is formed. Since Ge has a higher absorption coefficient, the photoelectric conversion rate becomes higher than that of silicon. Therefore, sensitivity of a solid-state imaging device can be enhanced.

Examples of usable material for the window layer that is the third semiconductor include Ge, SiGe, Si, InSb, InAs, GaSb, HgTe, HgSe, PbSe, PbS, PbTe, HgCdTe, InGaAs, AsSex, AsSx, SiCx, SiNx, GeNx, Se, GaAs, InP, AlAs, BP, InN, AlAs, GaP, AlP, GaN, BN, AlN, CdTe, CdSe, HgS, ZnTe, CdS, ZnSe, MnSe, MnTe, MgTe, MnS, MgSe, ZnS, MgS, HgI₂, PbI₂, and TlBr.

Examples of usable material for the well layer that is the first semiconductor include Ge, SiGe, InSb, InAs, GaSb, HgTe, HgSe, PbSe, PbS, PbTe, HgCdTe, and InGaAs.

Examples of usable material for the barrier layer include Si, C, AsSex, AsSx, SiOx, GeOx, MgOx, AlOx, ZrOx, HfOx, YOx, LaOx, SiCx, SiOxNy, SiNx, GeNx, Se, GaAs, InP, AlAs, BP, InN, AlAs, GaP, AlP, GaN, BN, AlN, CdTe, CdSe, HgS, ZnTe, CdS, ZnSe, MnSe, MnTe, MgTe, MnS, MgSe, ZnS, MgS, HgI₂, PbI₂, and TlBr.

It is more preferable that a material including any one of SiOx, GeOx, MgOx, AlOx, ZrOx, HfOx, YOx, LaOx, SiOxNy, SiNx, BN, AlN, and C is used for the barrier layer.

### Second Exemplary Embodiment

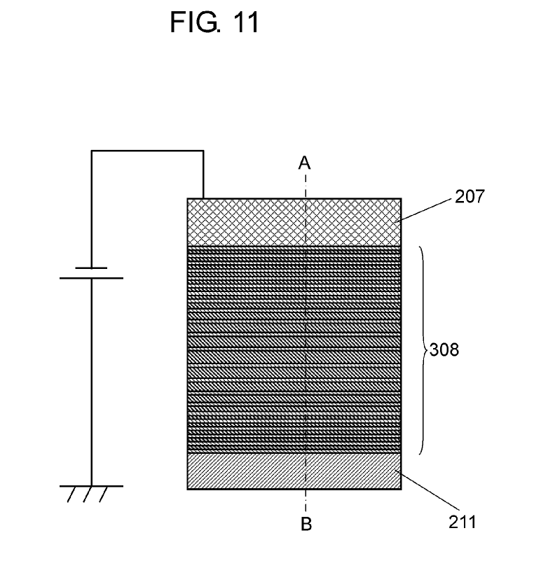

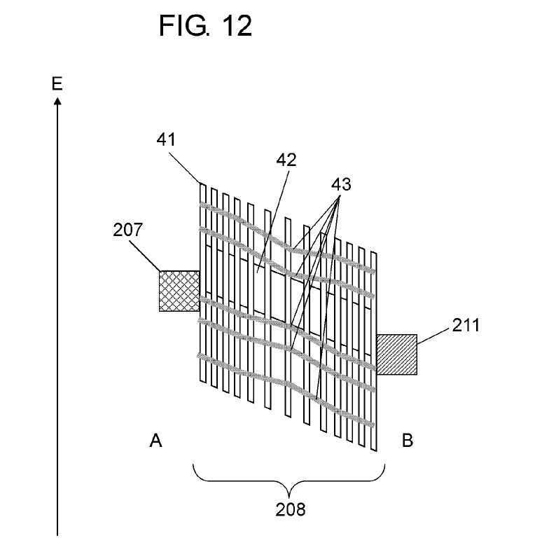

The second exemplary embodiment of the present invention will be described with reference to FIGS. 11 and 12.

Only the different point between the second exemplary embodiment and the first exemplary embodiment will be described, and the similar points will not be repeated.

FIG. 11 is an enlarged view of photoelectric conversion film 308 according to the second exemplary embodiment. The second exemplary embodiment is different from the first exemplary embodiment illustrated in FIG. 3 in that the thickness of a well layer, sandwiched between upper electrode 207 and pixel electrode 211, at a central part of photoelectric conversion film 308 is larger.

Specifically, at least one of well layers in a laminated structure has larger thickness than the other well layers.

With this structure, photoelectric conversion film 308 according to the second exemplary embodiment can exhibit absorption rate of about 55% for near-infrared light with a wavelength of 1300 nm.

Specifically, the well layer having the thickness larger than the other well layers has a band gap in a wavelength region ranging from near-infrared light to infrared light.

Thus, the solid-state imaging device can photograph in a dark place with high sensitivity, and is useful for a monitoring camera. This point will be described in more detail.

As illustrated in FIG. 11, the solid-state imaging device includes upper electrode 207, photoelectric conversion film 308, and pixel electrode 211 formed below photoelectric conversion film 308. The superlattice photoelectric conversion film is formed with the laminated structure of SiO₂ 2 nm/(Ge 2 nm/SiO₂ 2 nm)×5/(Ge 3 nm/SiO₂ 2 nm)×2/(Ge 4 nm/SiO₂ 2 nm)×2/(Ge 5 nm/SiO₂ 2 nm)×2/(Ge 6 nm/SiO₂ 2 nm)×2/(Ge 7 nm/SiO₂ 2 nm)×2/(Ge 8 nm/SiO₂ 2 nm)×2/(Ge 9 nm/SiO₂ 2 nm)×2/(Ge 10 nm/SiO₂ 2 nm)×30/(Ge 9 nm/SiO₂ 2 nm)×2/(Ge 8 nm/SiO₂ 2 nm)×2/(Ge 7 nm/SiO₂ 2 nm)×2/(Ge 6 nm/SiO₂ 2 nm)×2/(Ge 5 nm/SiO₂ 2 nm)×2/(Ge 4 nm/SiO₂ 2 nm) x 2/(Ge 3 nm/SiO₂ 2 nm)×2/(Ge 2 nm/SiO₂ 2 nm)×5/from pixel electrode 211.

FIG. 12 is a schematic diagram illustrating an energy band structure in a cross-sectional direction (A-B) from upper electrode 207 to pixel electrode 211 in FIG. 11. Charges generated by the photoelectric conversion are accelerated to pixel electrode 211 via superlattice miniband 43 by an electric field applied between upper electrode 207 and pixel electrode 211, and transferred to floating diffusion portion 215 from pixel electrode 211. Silicon oxide film layer 41 is located at both terminal ends of the superlattice photoelectric conversion film, and ITO of upper electrode 207 and Al of pixel electrode 211 are connected via SiO₂.

As illustrated in FIG. 12, a rectangular potential made of an upper end of a valence band and a lower end of a conductive band of silicon oxide film layer 41 and Ge layer 42 is confirmed. Since the thickness of Ge layer 42 that is the well layer is changed, and the influence of the barrier layer becomes high in the region where the well layer is thin, an apparent band gap by a miniband becomes wider. On the other hand, the band gap becomes small in the region where the well layer is thick, since the influence of the barrier layer is low. Accordingly, when the thicknesses of the well layers close to upper electrode 207 and pixel electrode 211 are further reduced, the band gap is increased to realize the effect of reducing dark current. Thus, sensitivity is enhanced, and infrared light can be detected, at the middle portion between upper electrode 207 and pixel electrode 211.

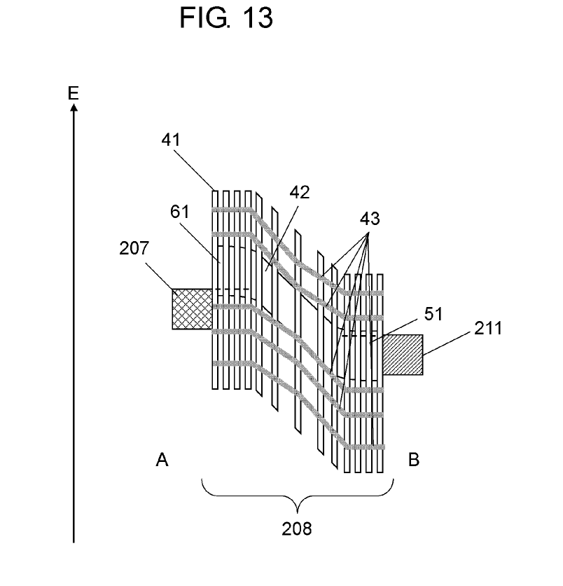

As illustrated in FIG. 13, in the present second exemplary embodiment, dark current can also be reduced by P-I-N diode formed by doping impurities as illustrated in the second modification of the first exemplary embodiment. As in the other modifications of the first exemplary embodiment, Schottky diode or P-I-N diode can be formed, or loss of signal charges can be reduced by a window effect attained by a semiconductor in which Si is located at terminal ends of a superlattice.

In the above first and second exemplary embodiments, the Ge/SiO₂ superlattice has been described as an example. However, a miniband is formed to realize the similar effect of reducing dark current by forming a superlattice including a semiconductor having a narrow band gap and a semiconductor having a relatively large band gap or an insulator.

### Third Exemplary Embodiment

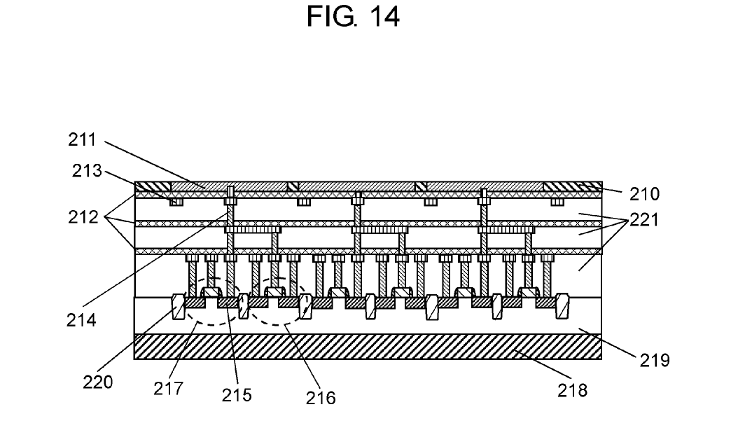

A manufacturing method of a solid-state imaging device according to the present invention will be described below with reference to FIGS. 14 to 16. FIGS. 14 to 16 are sectional views illustrating the manufacturing method of the solid-state imaging device according to the third exemplary embodiment. The components denoted by the reference numerals same as those in the first exemplary embodiment will not be described again.

As illustrated in FIG. 14, a wiring layer and pixel electrode 211 including Al are formed on silicon substrate 218 by a conventional method.

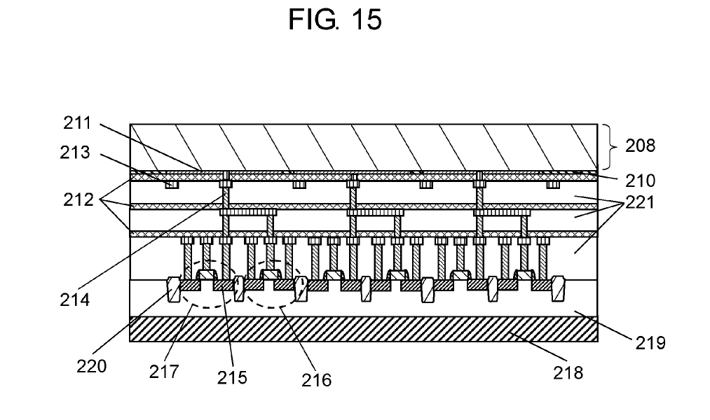

Next, photoelectric conversion film 208 is formed on pixel electrode 211 and the wiring layer as illustrated in FIG. 15. A silicon oxide film layer and a Ge layer are alternately laminated with their thicknesses being controlled by a sputtering method at room temperature. In this case, when an impurity is doped into the Ge layer as in the modification of the first exemplary embodiment, B₂H₆, PH₃, and H₂ gas is introduced in a chamber during the formation of the Ge layer. As in the modification of the first exemplary embodiment, the third semiconductor can be formed at both ends of photoelectric conversion film 208. As in the second exemplary embodiment, the thickness of the Ge layer can be increased in the vicinity of the center of photoelectric conversion film 208. When a solid-state imaging device having a window layer is manufactured, Si is formed by a sputtering method before the formation of the superlattice photoelectric conversion film and before the formation of upper electrode 207. The method of doping an impurity is similar to that described above.

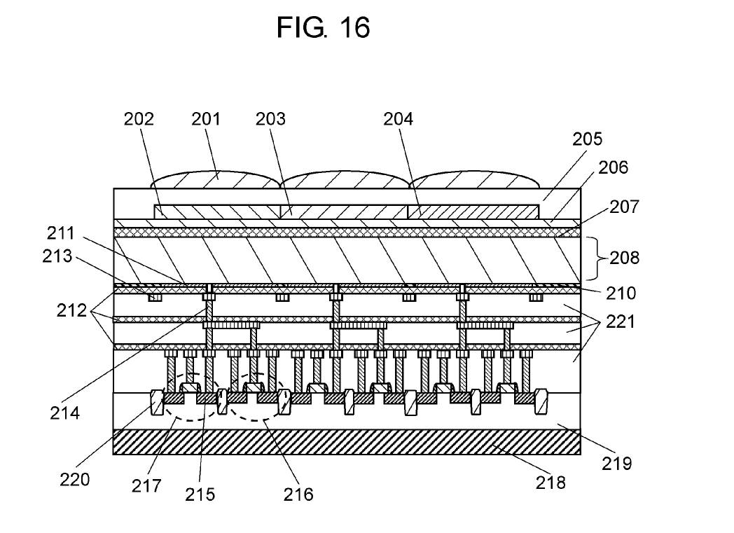

Then, as illustrated in FIG. 16, the components from upper electrode 207 made of ITO to microlens 201 are formed by the conventional method. Thus, the solid-state imaging device according to the present invention can be manufactured.

The solid-state imaging device according to the present invention has enhanced sensitivity and color mixture characteristic, and can realize high image quality, even if a pixel size is reduced. The solid-state imaging device is particularly applicable to an imaging device that needs to be compact and to have increased number of pixels, such as a digital still camera. Particularly, the solid-state imaging device can enhance image quality at night.

What is claimed is:

1. A solid-state imaging device comprising:
a semiconductor substrate including an imaging region and a peripheral circuit region;
a wiring layer formed on the semiconductor substrate;
a plurality of pixel electrodes arranged in a matrix on the wiring layer above the imaging region;
a photoelectric conversion film formed on the wiring layer and the plurality of pixel electrodes above the imaging region; and
an upper electrode formed on the photoelectric conversion film,
wherein the photoelectric conversion film has a laminated structure in which a plurality of well layers and a plurality of barrier layers are alternately laminated, each of the well layers being made of a first semiconductor having a fundamental absorption edge in a wavelength region longer than a near-infrared light wavelength, and each of the barrier layers being made of an insulator or a second semiconductor having a band gap wider than that of the first semiconductor.

2. The solid-state imaging device according to claim 1, wherein one layer of the plurality of barrier layers is in contact with the pixel electrode and another one layer of the plurality of barrier layers is in contact with the upper electrode in the photoelectric conversion film.

3. The solid-state imaging device according to claim 2, wherein a well layer, closer to the pixel electrode, out of the plurality of well layers has a first conductive type, and the photoelectric conversion film forms an ohmic contact with the pixel electrode via the barrier layer that is in contact with the pixel electrode, and
wherein a well layer, closer to the upper electrode, out of the plurality of well layers has a second conductive type opposite to the first conductive type, and the photoelectric conversion film forms an ohmic contact with the upper electrode through the barrier layer that is in contact with the upper electrode.

4. The solid-state imaging device according to claim 2, wherein
a well layer, closer to the upper electrode, out of the plurality of well layers has a first conductive type, and
the photoelectric conversion film forms a Schottky contact with the upper electrode through the barrier layer that is in contact with the upper electrode.

5. The solid-state imaging device according to claim 1, wherein one layer of the photoelectric conversion film is in contact with the pixel electrode and another one layer of the photoelectric conversion film is in contact with the upper electrode, and the one layer and the another layer are made of a third semiconductor having a band gap narrower than that of the barrier layer.

6. The solid-state imaging device according to claim 5, wherein
the third semiconductor in contact with the pixel electrode has a first conductive type, and forms an ohmic contact with the pixel electrode, and
the third semiconductor in contact with the upper electrode has a second conductive type opposite to the first conductive type, and forms an ohmic contact with the upper electrode.

7. The solid-state imaging device according to claim 5, wherein the third semiconductor in contact with the upper electrode has a first conductive type, and forms a Schottky contact with the upper electrode.

8. The solid-state imaging device according to claim 5, wherein the third semiconductor includes any one of Ge, SiGe, Si, InSb, InAs, GaSb, HgTe, HgSe, PbSe, PbS, PbTe, HgCdTe, InGaAs, AsSex, AsSx, SiCx, SiNx, GeNx, Se, GaAs, InP, AlAs, BP, InN, AlAs, GaP, AlP, GaN, BN, AlN, CdTe, CdSe, HgS, ZnTe, CdS, ZnSe, MnSe, MnTe, MgTe, MnS, MgSe, ZnS, MgS, HgI₂, PbI₂, and TlBr.

9. The solid-state imaging device according to claim 1, wherein the first semiconductor includes any one of Ge, SiGe, InSb, InAs, GaSb, HgTe, HgSe, PbSe, PbS, PbTe, HgCdTe, and InGaAs.

10. The solid-state imaging device according to claim 1, wherein the barrier layer includes any one of Si, C, AsSex, AsSx, SiOx, GeOx, MgOx, AlOx, ZrOx, HfOx, YOx, LaOx, SiCx, SiOxNy, SiNx, GeNx, Se, GaAs, InP, AlAs, BP, InN, AlAs, GaP, AlP, GaN, BN, AlN, CdTe, CdSe, HgS, ZnTe, CdS, ZnSe, MnSe, MnTe, MgTe, MnS, MgSe, ZnS, MgS, HgI₂, PbI₂, and TlBr.

11. The solid-state imaging device according to claim 10, wherein the barrier layer includes any one of SiOx, GeOx, MgOx, AlOx, ZrOx, HfOx, YOx, LaOx, SiOxNy, SiNx, BN, AlN, and C is used for the barrier layer.

12. The solid-state imaging device according to claim 1, wherein at least one of the well layers in the laminated structure has larger thickness than the other well layers.

13. The solid-state imaging device according to claim 12, wherein the well layer having the thickness larger than the other well layers has a band gap in a wavelength region ranging from near-infrared light to infrared light.

14. A manufacturing method of a solid-state imaging device, the method comprising:
forming a wiring layer on a semiconductor substrate including an imaging region and a peripheral circuit region;
forming a plurality of pixel electrodes arranged in a matrix on the wiring layer above the imaging region;
forming a photoelectric conversion film on the wiring layer and the plurality of pixel electrodes above the imaging region; and
forming an upper electrode on the photoelectric conversion film,
wherein, in a step of forming the photoelectric conversion film, a plurality of well layers and a plurality of barrier layers are alternately laminated, each of the well layers being made of a first semiconductor having a fundamental absorption edge in a wavelength region longer than a near-infrared light wavelength, and each of the barrier layers being made of an insulator or a second semiconductor having a band gap wider than that of the first semiconductor.
